(19) United States
(12) Patent Application Publication
(10) Pub. No.: US 2026/0093182 A1
(43) Pub. Date: Apr. 2, 2026

(54) DETERMINING POTENTIAL DEFECTS IN MASK PATTERNS

(71) Applicant: GDM Holding LLC, Mountain View, CA (US)

(72) Inventors: Abdalaziz I.M. Awad, Mountain View, CA (US); Cyrus Behroozi, Menlo Park, CA (US)

(21) Appl. No.: 19/339,435

(22) Filed: Sep. 25, 2025

Related U.S. Application Data
(60) Provisional application No. 63/702,663, filed on Oct. 3, 2024.
(60) Provisional application No. 63/701,758, filed on Oct. 1, 2024.

(51) Int. Cl. G03F 7/00; G03F 1/20; G03F 1/70

(52) U.S. Cl. CPC G03F 7/70508; G03F 1/20; G03F 1/70; G03F 7/705

(57) ABSTRACT

The technology involves differentiable mask manufacturing model that helps predict defects on the wafer. According to one aspect, a method includes receiving a mask design. Based on a gradient optimization, one or more parameters of one or more convolution kernels of a mask manufacturing model is determined. Using the one or more parameters of the one or more convolution kernels of the mask manufacturing model, a simulated mask pattern is generated based on the mask design. Whether the simulated mask pattern includes a defect is determined. Whether the mask design needs to be adjusted to avoid defects may also be determined.

### CROSS REFERENCE TO RELATED APPLICATIONS

The present application claims the benefit of and priority to U.S. Provisional Application No. 63/701,758, filed October 1, 2024, and to U.S. Provisional Application No. 63/702,663, filed October 3, 2024, the entire disclosures of which are hereby incorporated herein by reference.

### BACKGROUND

Improving semiconductor processes and systems, and increasing yield from semiconductor processes and systems, may include modeling of many, if not all, processing steps associated with these semiconductor processes and systems. One such semiconductor process is lithography. Non-limiting examples of lithography processing steps include exposure, resist development, and mask-writing. Existing approaches may be subject to noise, optical diffraction, diffusion, and other lithography-related issues.

### SUMMARY

A challenge in lithography optimizations is manufacturability of a mask design determined by lithography optimizations. Another challenge is performing lithography optimizations that are mask-manufacturing aware (e.g., mask-writing aware). Lithography optimizations, such as inverse lithography (ILT), can be used to determine photomask designs that provide viable yields and process windows. However, ILT may determine mask designs that cannot be manufactured.

Other approaches include using rule-based corrections to eliminate features from photomask designs that cannot be manufactured. These other approaches limit lithography optimizations by limiting design space and exploration thereof. Rule-based corrections may eliminate potential photomask designs that are actually manufacturable.

Aspects of the technology disclosed herein include using lithography models (e.g., compact and/or differentiable lithography models) in association with lithography optimizations (e.g., ILT). By way of example, convolutions to capture and represent the mask manufacturing process distortions can be included in forward passes of ILT, thereby making the ILT mask-manufacturing aware.

There are two aspects of mask manufacturing of which to be aware. One aspect is manufacturing constraints. There may be photomask designs that are unmanufacturable. By way of example, an unmanufacturable photomask design may have features (e.g., “islands” or “holes”) that are too small to manufacture. The other aspect is manufacturing distortion. A target photomask design is never manufactured with absolutely perfect fidelity. By way of example, corners may be rounded and/or line widths may be biased wider or narrower. A lithography design that is optimized according to approaches disclosed herein to be mask-manufacturing aware can anticipate manufacturing distortions and propose a “predistorted” target photomask design that, when manufactured, yields a mask pattern that prints accurately. In other words, instead of ILT being reactive to concerns and/or constraints associated with mask manufacturing as in other approaches, the approaches disclosed herein are proactive by taking concerns and/or constraints associated with mask manufacturing into account via use of lithography models. Other approaches are not mask-manufacturing aware and ignore one or both aspects discussed above and propose photomask designs that are unmanufacturable or expected to be manufactured with absolutely perfect fidelity.

Aspects of the technology disclosed herein include using lithography models in association with forward lithography simulation models to provide accurate predictions of yield and/or defectivity. The technical benefits of the disclosed technology include prediction of defects that may occur on semiconductor wafers downstream from one or more lithography processes (e.g., mask manufacturing) that are not predicted by other approaches.

According to one aspect of the technology, a method includes receiving, by one or more processors, a mask design; determining, by the one or more processors based at least on a gradient optimization, one or more parameters of one or more convolution kernels of a mask manufacturing model; generating, by the one or more processors using the one or more parameters of the one or more convolution kernels of the mask manufacturing model, a simulated mask pattern based at least on the mask design; and determining, by the one or more processors, whether the simulated mask pattern includes a defect. This may also include generating a simulated wafer pattern based on a lithography simulation of the simulated mask pattern.

In an example, the method may include adjusting, by the one or more processors, the mask design based at least on a determination that the simulated mask pattern includes the defect. Here, the method may include generating, using the mask manufacturing model, another simulated mask pattern based at least on the adjusted mask design. Whether the other simulated mask pattern includes a defect may be determined.

Alternatively or additionally to the above, the method may include, prior to generating the simulated mask pattern, initializing one or more convolution kernels of the mask manufacturing model. Here, initializing the one or more convolution kernels may include initializing a first kernel of the one or more convolution kernels as a gaussian kernel with a sigma corresponding to a point spread function (of a mask writing tool). Initializing the one or more convolution kernels may further include initializing a second kernel of the one or more convolution kernels as another gaussian kernel with a random, positive sigma.

Alternatively or additionally to the above, the method may include determining one or more convolutions of the mask design with one or more kernels. A threshold may be applied to the one or more convolutions to generate one or more thresholded convolutions. Here, generating the simulated mask pattern may be further based at least on the thresholded convolutions. The method may include prior to determining the one or more convolutions, converting the mask design to a raster format (e.g., a binary format).

Alternatively or additionally to the above, the method may include training, based on the simulated mask pattern, a machine learning model to adjust the mask design.

According to another aspect of the technology, a system is provided that comprises memory configured to store at least one of a mask design and a mask manufacturing model, and one or more processors operatively coupled to the memory. The one or more processors are configured to: determine, based at least on a gradient optimization, one or more parameters of one or more convolution kernels of the mask manufacturing model; generate, using the one or more parameters of the one or more convolution kernels of the mask manufacturing model; and determine whether the simulated mask pattern includes a defect.

In an example, the one or more processors may be further configured to adjust the mask design based at least on a determination that the simulated mask pattern includes the defect. Here, the one or more processors may be further configured to generate, using the mask manufacturing model, another simulated mask pattern based at least on the adjusted mask design. Whether the other simulated mask pattern includes a defect may be determined.

Alternatively or additionally to the above, the one or more processors may be further configured to, prior to generation of the simulated mask pattern, initialize one or more convolution kernels of the mask manufacturing model. Here, initialization of the one or more convolution kernels may include initialization of a first kernel of the one or more convolution kernels as a gaussian kernel with a sigma corresponding to a point spread function. Initialization of the one or more convolution kernels may further include initialization of a second kernel of the one or more convolution kernels as another gaussian kernel with a random, positive sigma.

Alternatively or additionally to the above, the one or more processors may be further configured to determine one or more convolutions of the mask design with one or more kernels. A threshold may be applied to the one or more convolutions to generate one or more thresholded convolutions. Here, generation of the simulated mask pattern may be further based at least on the thresholded convolutions. The one or more processors may be further configured to, prior to determination of the one or more convolutions, convert the mask design to a raster format (e.g., a binary format or a grayscale format).

Alternatively or additionally to the above, the one or more processors may be further configured to train, based on the simulated mask pattern, a machine learning model to adjust the mask design.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates an integrated circuit design flow in accordance with aspects of the technology.

FIG. 2 illustrates an example system that may be employed with aspects of the technology.

FIG. 3 illustrates an example of a mask design in accordance with aspects of the technology.

FIG. 4 illustrates an example of a mask-manufacturing-simulated mask design in accordance with aspects of the technology.

FIG. 5 illustrates an example of a lithography-simulated mask pattern in accordance with other approaches.

FIG. 6 illustrates an example of a scanning electron microscope (SEM) image data of a manufactured mask pattern in accordance with aspects of the technology.

FIG. 7 illustrates an example of a lithography-simulated mask pattern in accordance with aspects of the technology.

FIG. 8 illustrates an example of a mask design in accordance with aspects of the technology.

FIG. 9 illustrates an example of a mask-manufacturing-simulated mask design in accordance with aspects of the technology.

FIG. 10 illustrates an example of a lithography-simulated mask pattern in accordance with other approaches.

FIG. 11 illustrates an example of a SEM image data of a manufactured mask pattern in accordance with aspects of the technology.

FIG. 12 illustrates an example of a lithography-simulated mask pattern in accordance with aspects of the technology.

FIG. 13 illustrates an example method in accordance with aspects of the technology.

### DETAILED DESCRIPTION

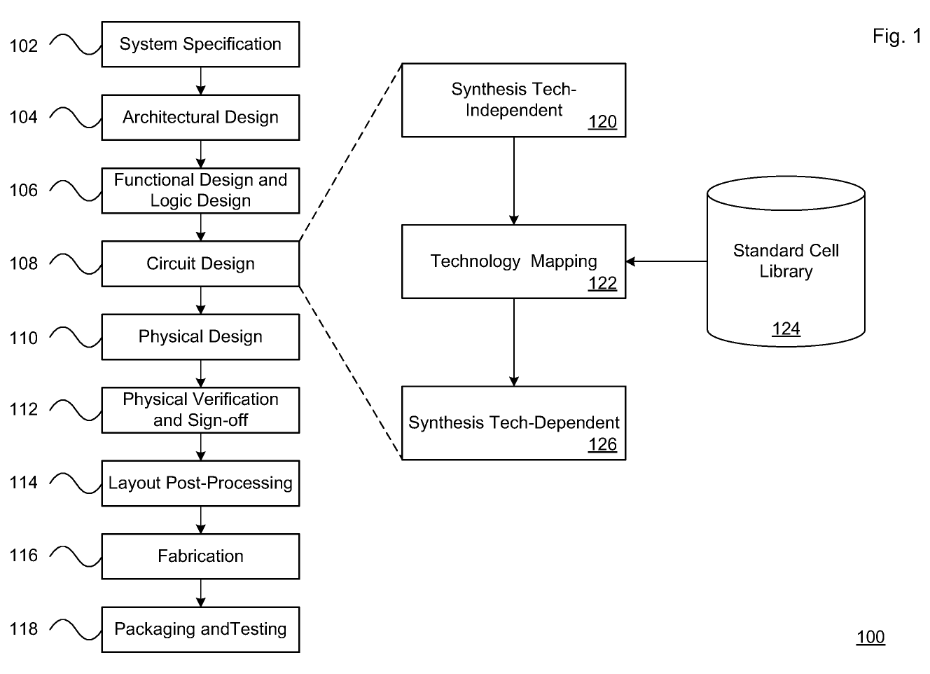

FIG. 1 illustrates an exemplary integrated circuit design flow 100 for use with aspects of the technology, including generating a circuit design and/or fabricating an integrated circuit that incorporates determining potential manufacturing defects in a mask pattern. As shown, the design flow may include preparing a system specification at block 102, such as to identify system-level requirements for the integrated circuit. The system specification is intended to capture the overall goal of the desired integrated circuit. This may include determining the device’s cost, performance, general architecture, how off-chip communication will be conducted, etc. The process flow may also include performing architectural design at block 104. At this stage, the design’s architecture and its layout are determined by design engineers. This can include integration of memory management, analog and/or mixed-signal components, on-device and external communication, any power constraints, choice of process technology and/or layer stacks, etc.

The process flow continues with performing functional design and logic design at block 106, and performing circuit design at block 108. Functional design may include refinement of the design’s specification to achieve the functional behavior of the desired system. Logic design involves adding the design’s structure to a behavioral representation of the desired design. Here, considerations include logic minimization, performance enhancement, as well as testability. This stage may consider problems associated with test vector generation, error detection and correction, and the like. By way of example, the functional design and logic design may include generating a behavioral model description (e.g., using HDL) and floor-planning. During circuit design, logic blocks are replaced by corresponding electronic circuits, which may include devices such as resistors, capacitors, and/or transistors. At this stage, circuit simulation may be performed in order to verify timing behavior and other constraints of the system. A Spice tool or other program may be used for circuit simulation.

Once the circuit design is complete, physical design may be performed at block 110 (e.g., component and wiring placement and routing), followed by physical verification and sign-off at block 112 (e.g., to obtain GDSII information with shapes to form the masks used to create the layers for fabricating the integrated circuit). During physical design, the actual layout of the integrated circuit is performed. Here, all of the components are placed and interconnected using metal interconnections. During this stage, the system may perform optimization of curvilinear interconnects, alternatively or additionally to any other layout operations. A circuit design that is able to pass testing of a circuit simulator in the circuit design stage may be found to be faulty after it has been packaged, e.g., due to geometric design rule issues. Thus, physical design rules are followed to ensure correctness during chip fabrication. Errors may include short or open circuits, open channels, or other issues may result when physical design rules are not followed. During physical verification and sign-off, the system performs any verification steps that are required before chip manufacturing. This can include design rule checking and correction, timing simulation, electromagnetic simulation, etc.

Layout post-processing occurs at block 114, then fabrication at block 116, and the packaging and testing at block 118. At block 114, the layout post-processing may include geometry processing before actual manufacturing, e.g., any dummy fill insertion, correction for optical proximity, mask optimization, etc. Fabrication comprises semiconductor manufacturing, which includes stages such as lithography patterning (masking), baking or annealing, etching, etc. Then the raw die of the chip is inserted into a package and I/O pins are connected to the package at block 118. Testing of the chip also occurs at this stage.

As shown, in the circuit design phase of block 108, the process may involve technology-independent synthesis at block 120. This step involves transferring the circuit definitions, such as register-transfer-level (RTL) descriptions, into generic data structures such as And-inverter graph (AIG), and optimizing the circuit in terms of nodes and levels. At block 122, technology mapping is performed based on information from a standard cell library 124. This step involves maps the generic optimized AIG descriptions into real, manufacturable standard cells included in the standard cell library. From this, technology-dependent synthesis is then performed at block 126. This step further optimizes the circuit defined in the gate-level netlist in terms of power, performance and area, using standard-cell-based definitions from block 122.

### EXAMPLE INTEGRATED CIRCUIT DEVELOPMENT SYSTEM

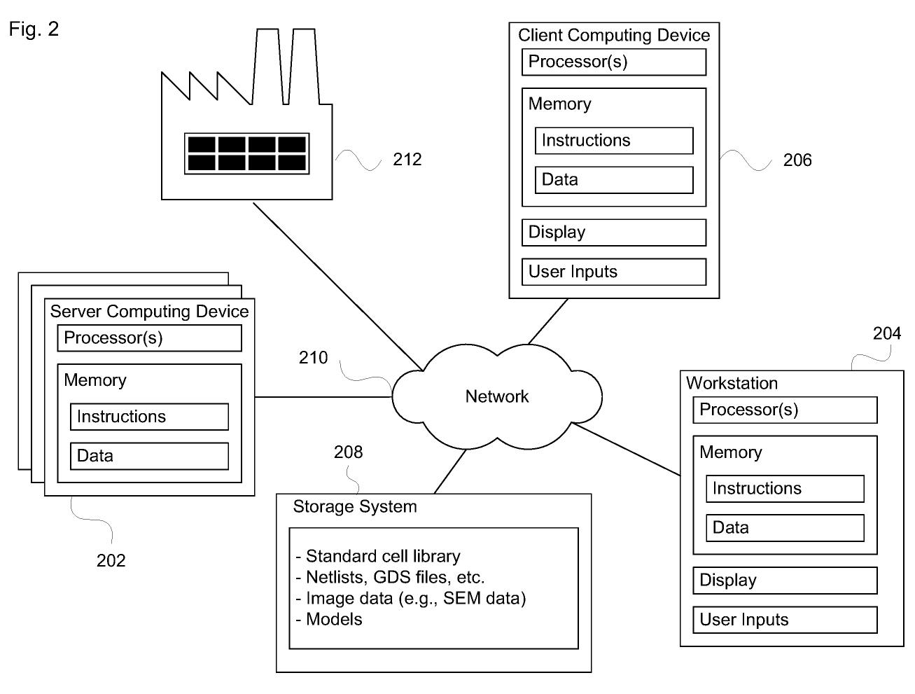

One example of a system for performing circuit design and fabrication is shown in FIG. 2. In particular, FIG. 2 is a functional diagram, of an example system 200 that includes a plurality of computing devices 202, 204, 206 and a storage system 208 connected via a network 210. System 200 may also include a fabrication facility 212 that is configured to produce integrated circuits designed according to the processes described herein. As shown in FIG. 2, each of computing devices 202, 204 and 206 may include one or more processors, memory, data and instructions.

By way of example, the one or more processors may be any conventional processors, such as commercially available central processing units (CPUs), graphical processing units (GPUs) or tensor processing units (TPUs). Alternatively, the one or more processors may include a dedicated device such as an ASIC or other hardware-based processor. As shown in FIG. 2, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

Moreover, reference to “one or more processors” herein includes situations where a set of processors may be configured to perform one or more operations. Any combination of such a set of processors may perform individual operations or a group of operations. This may include two or more CPUs, GPUs or TPUs (or other hardware-based processors) or any combination thereof. It may also include situations where the processors have multiple processing cores. Therefore, reference to “one or more processors” does not require that all processors (or cores) in the set must each perform all of the operations. Rather, unless expressly stated, any one of the one or more processors (or cores) may perform different operations when a set of operations is indicated, and different processors (or cores) may perform specific operations, either sequentially or in parallel.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance. The instructions may include a method for processing image data of a semiconductor wafer as discussed herein.

The data may be retrieved, stored or modified by processor in accordance with the instructions. For instance, although the claimed subject matter is not limited by any particular data structure, the data may be stored in computing device registers, in a relational database as a table having a plurality of different fields and records, XML documents or flat files, HDL information, GDSII information, etc. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 200 and/or the fabrication facility 212.

The various computing devices may communicate directly or indirectly via one or more networks, such as network 210. The network 210 and any intervening nodes may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 202 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 202 may include one or more server computing devices that are capable of communicating with computing devices 204, 206 and the fabrication facility 212 via the network 210. In some examples, client computing device 204 may be an engineering workstation used by a developer to perform circuit design and/or other processes for integrated circuit design and fabrication. Client computing device 206 may also be used by a developer, for instance to prepare system requirements for the integrated circuit or manage the manufacturing process with the fabrication facility 212.

Storage system 208 can be of any type of computerized storage capable of storing information accessible by the server computing devices 202, 204 and/or 206, such as a hard-drive, memory card, ROM, RAM, DVD, CD-ROM, flash drive and/or tape drive. In addition, storage system 208 may include a distributed storage system where data is stored on a plurality of different storage devices which may be physically located at the same or different geographic locations. Storage system 208 may be connected to the computing devices via the network 210 as shown in FIG. 2, and/or may be directly connected to or incorporated into any of the computing devices.

Storage system 208 may store various types of information. For instance, the storage system 208 may store models of lithography processing steps associated with determining potential manufacturing defects in a mask pattern and other processes as well as instructions for processing image data of a semiconductor wafer and other processes described herein.

### Differentiable Mask Process Modeling

Aspects of the technology provide techniques for mask manufacturing modeling that are compact, hybrid in being data and physics-driven, allowing for efficient integration with lithography optimization to unlock mask manufacturing-aware optimization. This can alleviate the demands for stringent and time-consuming mask-rule checks (MRCs). For instance, this can include using a mask manufacturing model having n convolution kernels. One of the n kernels can be initialized as a gaussian with a sigma equal to a point spread function of a particular lithography process or system (e.g., a particular laser mask writer). As used herein, “point spread function” refers to an impact range of a laser of a mask writer. A point spread function can be related to a wavelength of the laser and provide a simplistic indication of a “spread” of the laser. The remaining n-1 kernels can be initialized as gaussian convolution kernels with random positive sigma values.

By way of example, a mask manufacturing model can be simplified to the simplest physical form for a particular lithography process or system (e.g., a laser writer). For instance, a laser of a laser writer scans a photomask design, the laser may be activated for positive points of the photomask design and deactivated for negative points of the photomask design.

Parameters of convolution kernels can be based on a gradient optimization. Non-limiting examples of parameters of convolution kernels include how many convolution kernels, corresponding sigmas of these convolution kernels, asymmetries, and shifts from an origin. These convolution kernels can be applied to an image or image data to achieve a certain effect (e.g., optimize the image).

A gradient optimization can leverage differentiable lithography metrics as a loss function to compare an output of the mask manufacturing model to image data (e.g., scanning electron microscopic (SEM) image data, such as in raster format) associated with manufactured masks (e.g., masks formed on a semiconductor wafer). A flood-fill-based wafer image extraction and registration process may be performed on the design layout, as described and shown in Appendices 1 and 2, which are incorporated herein by reference in their entirety. A gradient optimization can be used to determine the best parameters for the convolution kernels) because the optimization multiple degrees of freedom. By way of example, a gradient optimization can explore design space to find the best parameters for convolution kernels. For example, mean-squared error (MSE) optimization metrics may be analogous to lithography metrics. The convolution kernels can be applied to a mask design determined by a mask manufacturing model. The result of the convolution will be a prediction of a manufactured mask pattern, which, for example, can be compared to a SEM image of a corresponding manufactured mask.

The technical benefits of the disclosed technology include parameters of mask manufacturing models being fit accurately on small datasets (e.g., thirty samples), light-weight kernels of mask manufacturing models enabling scaling to larger mask designs, and integration with lithography optimizations (e.g., ILT) with reduced processing resources (e.g., reduced computational overhead). Other technical benefits of the disclosed technology include a differentiable formulation of mask manufacturing that aids end-to-end modeling and optimization.

The approaches disclosed herein, which include integrating mask manufacturing models with lithography optimizations (e.g., ILT), can reduce, or even eliminate, use of mask rule checks (MRCs), thereby enabling end-to-end design for manufacturability. Lithography optimizations that account for (e.g., are aware of) mask-writing distortions via mask manufacturing models yield results (e.g., mask patterns) that are manufacturable. Therefore, the approaches disclosed herein explore design space more effectively and efficiently by avoiding mask designs that are not manufacturable.

As discussed herein, the disclosed technology can predict defects that can be caused by unaccounted or unexpected distortions in a mask. By predicting such defects, steps can be taken to prevent the predicted defects. For example, a photomask design or a raster pattern can be adjusted to mitigate and/or eliminate a predicted defect.

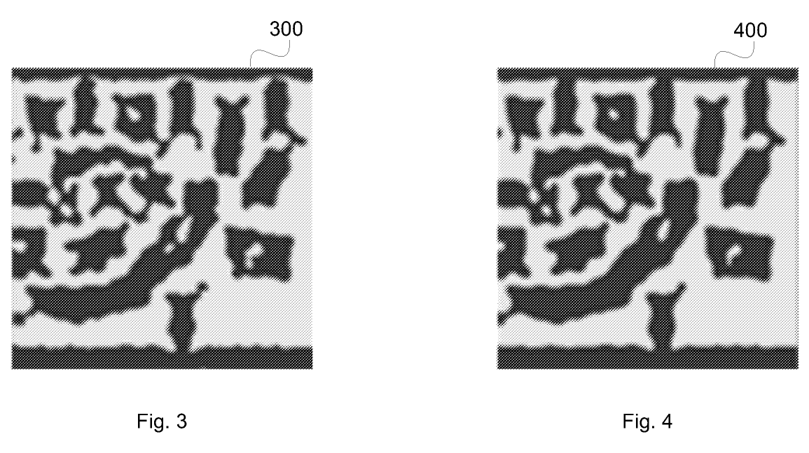

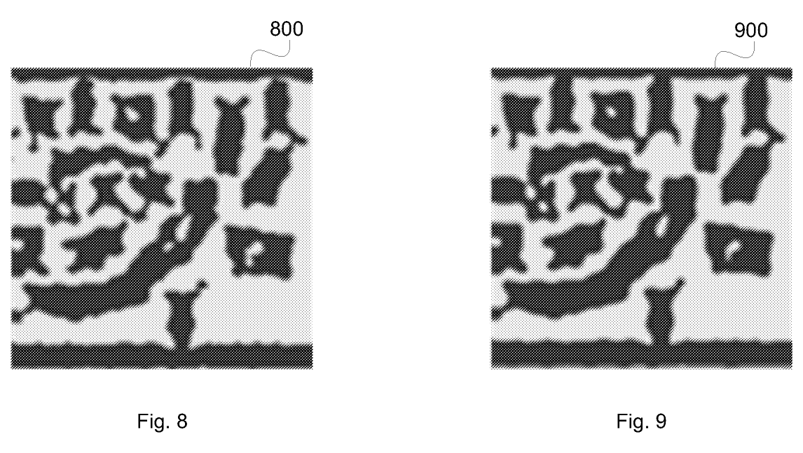

FIGS. 3-12 illustrate comparisons of a forward simulation of one or more lithography processes without a mask-manufacturing model according to other approaches and forward simulation of one or more lithography processes with a mask-manufacturing model according to approaches disclosed herein to predict or otherwise determine potential defects in a mask pattern formed on a semiconductor wafer. FIGS. 3-7 demonstrate that the disclosed technology accurately predicts manufactured mask patterns on wafers that include defects that other approaches do not. FIGS. 8-12 demonstrate that the disclosed technology accurately predicts manufactured mask patterns when there are no defects predicted.

FIG. 3 illustrates an example of a mask design 300 in accordance with aspects of the technology. The mask design 300 can be in GDSII or OASIS format, for example. However, the disclosed approaches are not so limited. The mask design 300 can be converted from GDSII or OASIS format to a raster format (e.g., a binary array).

FIG. 4 illustrates an example of a mask-manufacturing-simulated mask design 400 in accordance with aspects of the technology. The mask-manufacturing-simulated mask design 400 is based on the mask design 300. By way of example, the mask-manufacturing-simulated mask design 400 is produced by computing convolutions of the mask design 300 with calibrated kernels, and then applying a threshold.

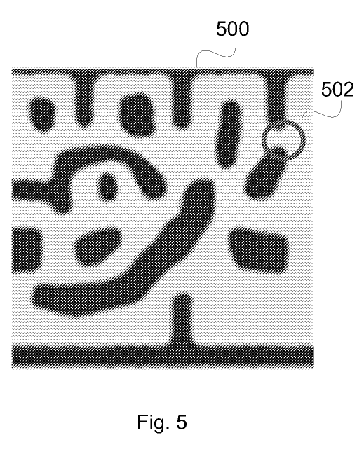

FIG. 5 illustrates an example of a lithography-simulated mask pattern 500 in accordance with other approaches. The lithography-simulated mask pattern 500 is based on the mask design 300.

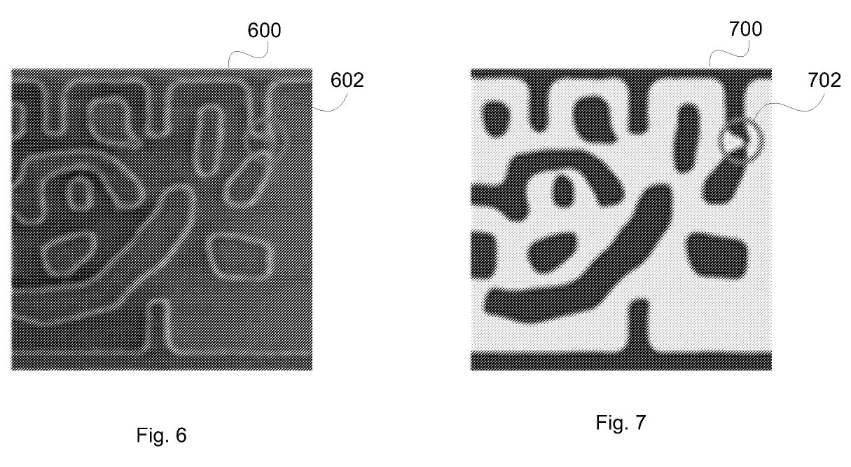

FIG. 6 illustrates an example of a SEM image data of a manufactured mask pattern 600 in accordance with aspects of the technology. The mask pattern 600 is manufactured based on the mask-manufacturing-simulated mask design 400 using a dosage of 30.8 millijoules (mJ) per square centimeter (cm²). However, the disclosed technology is not so limited. Processing of SEM image data, or equivalent data, may include flood-filling, such as that described herein and in Appendices 1-2.

The manufactured mask pattern 600 includes a defect within circle 602. This defect is a bridging defect. The circle 602 corresponds to circle 502 shown in FIG. 5. However, the lithography-simulated mask pattern 500 within the circle 502 does not include or indicate a defect in the manufactured mask pattern 600 because, unlike the disclosed approaches, other approaches are not mask-manufacturing aware.

FIG. 7 illustrates an example of a lithography-simulated mask pattern 700 in accordance with aspects of the technology. The lithography-simulated mask pattern 700 is based on the simulated mask design 400 and mask-manufacturing model using a dosage equivalent to 30.8 mJ per cm². As shown in the lithography-simulated mask pattern 700 within circle 702, which corresponds to circle 602 shown in FIG. 6, the lithography-simulated mask pattern 700 predicts a defect. That is, the lithography-simulated mask pattern 700 indicates that if the mask-manufacturing-simulated mask design 400 is used to manufacture a mask pattern, then that manufactured mask pattern would have the defect shown in the circle 702. This defect in the lithography-simulated mask pattern 700 closely resembles the bridging defect in the manufactured mask pattern 600 within the circle 602.

FIG. 8 illustrates an example of a mask design 800 in accordance with aspects of the technology. The mask design 800 can be in GDSII or OASIS format, for example. However, the disclosed approaches are not so limited. The mask design 800 can be converted from GDSII or OASIS format to a raster format (e.g., a binary array).

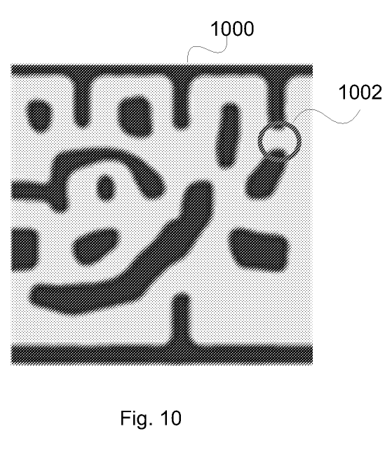

FIG. 9 illustrates an example of a mask-manufacturing-simulated mask design 900 in accordance with aspects of the technology. The mask-manufacturing-simulated mask design 900 is based on the photomask design 800. By way of example, the mask-manufacturing-simulated mask design 900 is produced by computing convolutions of the mask design 800 with calibrated kernels, and then applying a threshold.

FIG. 10 illustrates an example of a lithography-simulated mask pattern 1000 in accordance with other approaches. The lithography-simulated mask pattern 1000 is based on the simulated mask design 800.

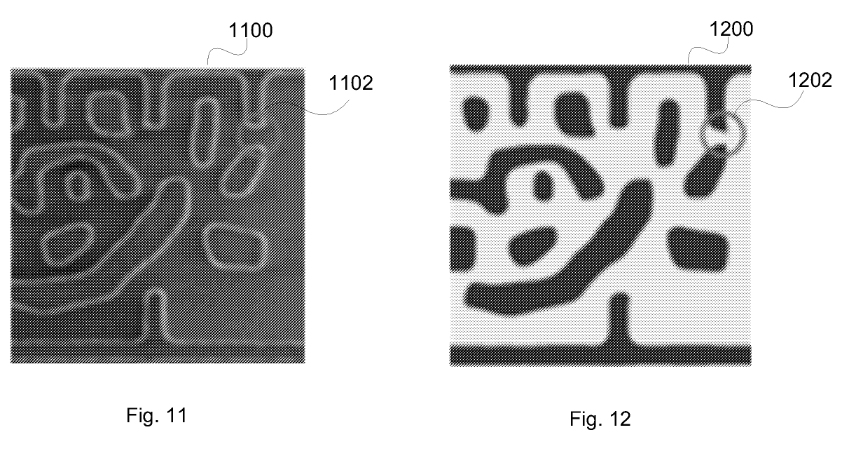

FIG. 11 illustrates an example of a SEM image data of a manufactured mask pattern 1100 in accordance with aspects of the technology. The mask pattern 1100 is manufactured based on the mask design 800, using a dosage of 32.8 mJ per cm². However, the disclosed technology is not so limited. Processing of SEM image data, or equivalent data, may include flood-filling, such as that described herein and in Appendices 1-2.

In contrast to the manufactured mask pattern 600, the manufactured mask pattern 1100 does not include a defect within circle 1102, which corresponds to the circles 602 and 1002 shown in FIGS. 6 and 10, respectively.

FIG. 12 illustrates an example of a lithography-simulated mask pattern 1200 in accordance with aspects of the technology. The lithography-simulated mask pattern 1200 is based on the mask-manufacturing-simulated photomask design 900 and a mask-manufacturing model, using a dosage equivalent to 32.8 mJ per cm². As in the manufactured mask pattern 1100, the simulated mask pattern 1200 does not include a defect within circle 1202, which corresponds to circle 1102 shown in FIG. 11. Thus, the lithography-simulated mask pattern 1200 closely resembles the manufactured mask pattern 1100 that does not have a defect.

In one approach, the technology may employ a machine learning-based mask process model as a solution for the aforementioned problems. This is an image-generation approach instead of the convolution-based approach discussed above. In this approach, the differentiable nature of the model allows it to be integrated with other parts of the lithography process simulation as discuss herein. The integration of differentiable mask process models can facilitate moving towards end-to-end mask optimization while eliminating most MRC requirements. Integrated mask process modeling is beneficial because it can aid in exploring the design space in mask optimizations more efficiently than existing approaches.

A generative network architecture may be employed. The network can be on original mask designs as inputs, and SEM images of the mask as outputs. An automated workflow may be used to pre-process high-noise mask SEM images and convert them into filled contour images for more efficient comparison with the mask design targets. By way of example, the data preparation workflow for SEM images may comprise a denoising step, followed by a contour extraction step and then by an overlay matching step to have the SEM contours registered with the design contours.

Automated SEM extraction and registration workflow may be combined with a flood-fill based technique, as discussed in Appendix 1 and shown in Appendix 2, to extract the hollow and possibly disconnected contours from the noisy SEM images and to convert them into binarized SEM polygons that are aligned with the design polygons. These binarized and aligned SEM polygons can be directly and precisely compared against target mask designs using differentiable metrics. With the aforementioned model and training data adjustments, effective performance has been shown with training datasets on the order of 100 samples, while maintaining the ability to generalize to different datasets and maintaining high accuracy on the order of 1-2 percent for MSEs and area errors. The model can also generalize and predict mask behavior at various image resolutions or length (size) scales. Here, the mask writing tool in question should be the same or similar. Moreover, such a model can be utilized as a general solution for any type of mask-writing tool.

It can be seen that model-based representations of mask writing processes diminish the need for rigid MRC approaches, thus enabling a more seamless end-to-end design for manufacturability when integrated with mask optimizations such as ILT. A mask optimization that is aware of the mask-writing distortions via a differentiable model will only propose mask patterns that are manufacturable and, thus, support efficient exploration of the mask design space.

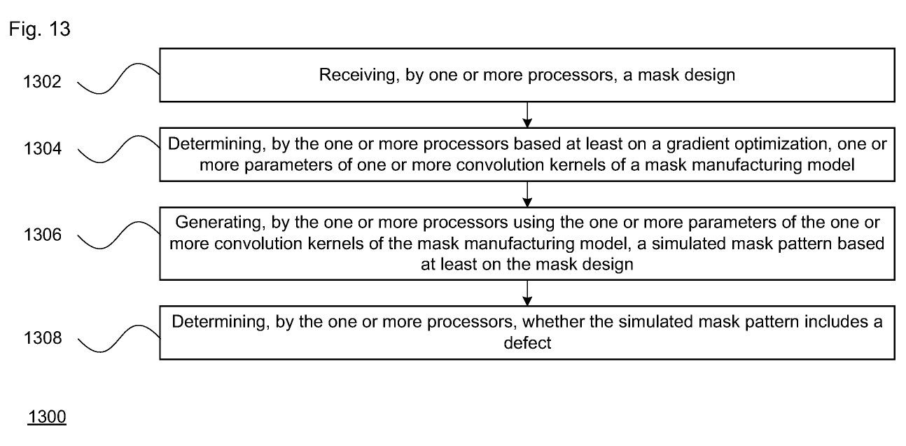

FIG. 13 illustrates an example method 1300 in accordance with the above discussion. The method 1300 includes, at block 1302, receiving, by one or more processors, a mask design. At block 1304, the method 1300 includes determining, by the one or more processors based at least on a gradient optimization, one or more parameters of one or more convolution kernels of a mask manufacturing model. At block 1306, the method 1300 includes generating, by the one or more processors using the one or more parameters of the one or more convolution kernels of the mask manufacturing model, a simulated mask pattern based at least on the photomask design. At block 1308, the method 1300 includes determining, by the one or more processors, whether the simulated mask pattern includes a defect.

Although the technology herein has been described with reference to particular embodiments and configurations, it is to be understood that these embodiments and configurations are merely illustrative of the principles and applications of the present technology. It is therefore to be understood that numerous modifications may be made to the illustrative embodiments and configurations, and that other arrangements may be devised without departing from the spirit and scope of the present technology as defined by the appended claims.

1. A method comprising:
receiving, by one or more processors, a mask design;
determining, by the one or more processors based at least on a gradient optimization, one or more parameters of one or more convolution kernels of a mask manufacturing model;
generating, by the one or more processors using the one or more parameters of the one or more convolution kernels of the mask manufacturing model, a simulated mask pattern based at least on the mask design; and
determining, by the one or more processors, whether the simulated mask pattern includes a defect.

2. The method of claim 1, further comprising, adjusting, by the one or more processors, the mask design based at least on a determination that the simulated mask pattern includes the defect.

3. The method of claim 2, further comprising:
generating, by the one or more processors using the mask manufacturing model, another simulated mask pattern based at least on the adjusted mask design; and
determining, by the one or more processors, whether the other simulated mask pattern includes the defect.

4. The method of claim 1, further comprising, prior to generating the simulated mask pattern, initializing, by the one or more processors, one or more convolution kernels of the mask manufacturing model.

5. The method of claim 4, wherein initializing the one or more convolution kernels includes initializing a first kernel of the one or more convolution kernels as a gaussian kernel with a sigma corresponding to a point spread function.

6. The method of claim 5, wherein initializing the one or more convolution kernels further includes initializing a second kernel of the one or more convolution kernels as another gaussian kernel with a random, positive sigma.

7. The method of claim 1, further comprising:
determining, by the one or more processors, one or more convolutions of the mask design with one or more kernels; and
applying, by the one or more processors, a threshold to the one or more convolutions to generate one or more thresholded convolutions.

8. The method of claim 7, wherein generating the simulated mask pattern is further based at least on the thresholded convolutions.

9. The method of claim 7, further comprising, prior to determining the one or more convolutions, converting, by the one or more processors, the mask design to a raster format.

10. The method of claim 1, further comprising training, by the one or more processors based on the simulated mask pattern, a machine learning model to adjust the mask design.

11. A system comprising:
memory configured to store at least one of a mask design and a mask manufacturing model; and
one or more processors operatively coupled to the memory, the one or more processors being configured to:
determine, based at least on a gradient optimization, one or more parameters of one or more convolution kernels of the mask manufacturing model;
generate, using the one or more parameters of the one or more convolution kernels of the mask manufacturing model, a simulated mask pattern based at least on the mask design; and
determine whether the simulated mask pattern includes a defect.

12. The system of claim 11, wherein the one or more processors are further configured to adjust the mask design based at least on a determination that the simulated mask pattern includes the defect.

13. The system of claim 12, wherein the one or more processors are further configured to:
generate, using the mask manufacturing model, another simulated mask pattern based at least on the adjusted mask design; and
determine whether the other simulated mask pattern includes the defect.

14. The system of claim 11, wherein the one or more processors are further configured to, prior to generation of the simulated mask pattern, initialize one or more convolution kernels of the mask manufacturing model.

15. The system of claim 14, wherein the one or more processors are further configured to initialize the one or more convolution kernels by being configured to initialize a first kernel of the one or more convolution kernels as a gaussian kernel with a sigma corresponding to a point spread function.

16. The system of claim 15, wherein the one or more processors are further configured to initialize the one or more convolution kernels by being configured to initialize a second kernel of the one or more convolution kernels initialized as another gaussian kernel with a random, positive sigma.

17. The system of claim 11, wherein the one or more processors are further configured to:
determine one or more convolutions of the mask design with one or more kernels; and
apply a threshold to the one or more convolutions to generate one or more thresholded convolutions.

18. The system of claim 17, wherein the one or more processors are further configured to generate the simulated mask pattern further based at least on the thresholded convolutions.

19. The system of claim 17, wherein the one or more processors are further configured to, prior to determination of the one or more convolutions, convert the mask design to a raster format.

20. The system of claim 11, wherein the one or more processors are further configured to train, based at least on the simulated mask pattern, a machine learning model to adjust the mask design.
